(19) United States
(12) Patent Application Publication
(10) Pub. No.: US 2026/0082794 A1
(43) Pub. Date: Mar. 19, 2026

(54) LIGHT-EMITTING DEVICE, DISPLAY DEVICE INCLUDING THE SAME AND ELECTRONIC DEVICE INCLUDING DISPLAY DEVICE

(71) Applicant: Samsung Display Co., LTD., Yongin-si (KR)

(72) Inventors: Hwi KIM, Yongin-si (KR); Jung Sun PARK, Yongin-si (KR); Ji Hee SON, Yongin-si (KR); Seoul Ki LEE, Yongin-si (KR); Areum LEE, Yongin-si (KR); Yeon Hwa LEE, Yongin-si (KR); Joon Gu LEE, Yongin-si (KR)

(21) Appl. No.: 19/228,020

(22) Filed: Jun. 4, 2025

(30) Foreign Application Priority Data
Sep. 13, 2024 (KR) 10-2024-0125555

(51) Int. Cl. H10K 59/80; H10K 50/17; H10K 102/10

(52) U.S. Cl. CPC H10K 59/80524; H10K 50/171; H10K 59/80518; H10K 2102/102; H10K 2102/103

(57) ABSTRACT

A light-emitting device includes a first electrode and a second electrode opposing each other; and a light-emitting layer disposed between the first electrode and the second electrode. The second electrode includes a main layer disposed on the light-emitting layer and including a pure metal material; and an anchor layer disposed on the main layer.

This application claims priority to Korean Patent Application No. 10-2024-0125555, filed on Sep. 13, 2024, and all the benefits accruing therefrom under 35 U.S.C. § 119, the content of which in its entirety is herein incorporated by reference.

### BACKGROUND

1. Field

The disclosure relates to a light-emitting device and a display device including the same.

### 2. Description of the Related Art

As an information society develops, the demand for a display device for displaying an image is increasing in various forms. For example, the display device is being applied to various electronic devices such as smartphones, digital cameras, laptop computers, navigation devices, and smart televisions.

The display device may be a flat panel display device such as a liquid crystal display device, a field emission display device, or a light-emitting display device. Here, the light-emitting display device may include an organic light-emitting display device including an organic light-emitting device, an inorganic light-emitting display device including an inorganic light-emitting device such as an inorganic semiconductor, and a micro or nano light-emitting display device including a micro or nano light-emitting device.

The organic light-emitting display device displays an image using light-emitting devices each including a light-emitting layer made of an organic light-emitting material. As such, as the organic light-emitting display device implements image display using self-light-emitting devices, the organic light-emitting display device may have relatively superior performance in terms of power consumption, response speed, emission efficiency, luminance, and wide viewing angle compared to other display devices.

One surface of the display device may be a display surface including a display area where an image is displayed. Light-emitting areas that emit light with respective luminance and color may be arranged in the display area.

### SUMMARY

The display device may include light-emitting devices disposed in the light-emitting areas.

Each of the light-emitting devices of the display device may include a first electrode and a second electrode facing each other, and a light-emitting layer disposed therebetween.

Light from the light-emitting layer may be reflected by one of the first electrode and the second electrode and emitted to the outside through the other of the first electrode and the second electrode. In an embodiment, when the first electrode reflects light, the light from the light-emitting layer may be emitted through the second electrode. In this case, the higher the transmittance of the second electrode, the more the light emission efficiency of the light-emitting device may be improved.

The first electrode may be a pixel electrode disposed in each of the light-emitting areas, while the second electrode may be a common electrode disposed throughout the light-emitting areas. In this case, the lower the resistance of the second electrode, the more the photoelectric conversion efficiency of the light-emitting device may be improved.

As the second electrode is disposed on the light-emitting layer, the light-emitting layer is easily damaged when using a plasma deposition process to thinly dispose the second electrode. Therefore, there is a problem that it is difficult to improve the photoelectric conversion efficiency of the light-emitting device.

Features of the disclosure provide a light-emitting device including a second electrode, capable of being disposed by a vacuum thermal deposition process and having relatively low resistance and relatively high light transmittance, and a display device including the same.

However, features of the disclosure are not restricted to those set forth herein. The above and other features of the disclosure will become more apparent to one of ordinary skill in the art to which the disclosure pertains by referencing the detailed description of the disclosure given below.

In an embodiment of the disclosure, there is provided a light-emitting device includes a first electrode and a second electrode opposing each other; and a light-emitting layer disposed between the first electrode and the second electrode. The second electrode includes a main layer disposed on the light-emitting layer and including a pure metal material; and an anchor layer disposed on the main layer.

In an embodiment, the main layer has a thickness of about 5 nanometers (nm) to about 30 nm. The pure metal material includes pure silver. The anchor layer has a thickness smaller than the thickness of the main layer.

In an embodiment, the anchor layer includes a metal material having a larger atomic weight than an atomic weight of the pure metal material or a larger atomic radius than an atomic radius of the pure metal material.

In an embodiment, the anchor layer includes at least one of tungsten oxide, indium tin oxide, and indium zinc oxide.

In an embodiment, the anchor layer includes at least one of ytterbium (Yb), bismuth (Bi), cesium (Cs), samarium (Sm), and barium (Ba).

In an embodiment, the thickness of the anchor layer is about 0.5 nm to about 3 nm.

In an embodiment, the first electrode reflects light from the light-emitting layer. The light-emitting layer is disposed on the first electrode. The second electrode is disposed on the light-emitting layer. The light from the light-emitting layer is emitted through the second electrode. The second electrode is covered with an electrode protective layer. The anchor layer is disposed between the main layer and the electrode protective layer.

In an embodiment, the light-emitting device further includes a first common layer disposed between the first electrode and the light-emitting layer; and a second common layer disposed between the light-emitting layer and the second electrode. The second common layer includes an electron transporting layer disposed on the light-emitting layer; and an electron injection layer disposed between the electron transporting layer and the second electrode. The electron injection layer includes ytterbium (Yb).

In an embodiment of the disclosure, there is provided a display device includes a substrate including a display area in which light-emitting areas are arranged; a circuit layer disposed on the substrate; and an element layer disposed on the circuit layer. The element layer includes light-emitting devices disposed in the light-emitting areas. each of the light-emitting devices includes a first electrode disposed on the circuit layer; a light-emitting layer disposed on the first electrode; and a second electrode disposed on the light-emitting layer. The second electrode includes a main layer disposed on the light-emitting layer and including a pure metal material; and an anchor layer disposed on the main layer.

In an embodiment, the main layer has a thickness of about 5 nm to about 30 nm. The pure metal material includes pure silver. The anchor layer has a thickness smaller than the thickness of the main layer.

In an embodiment, the anchor layer includes a metal material having a larger atomic weight than an atomic weight of the pure metal material or a larger atomic radius than an atomic radius of the pure metal material.

In an embodiment, the anchor layer includes at least one of tungsten oxide, indium tin oxide, and indium zinc oxide.

In an embodiment, the anchor layer includes at least one of ytterbium (Yb), bismuth (Bi), cesium (Cs), samarium (Sm), and barium (Ba).

In an embodiment, the thickness of the anchor layer is about 0.5 nm to about 3 nm.

In an embodiment, the display device further includes an electrode protective layer covering the second electrode of the element layer. The first electrode reflects light from the light-emitting layer. The light from the light-emitting layer is emitted through the second electrode. The anchor layer is disposed between the main layer and the electrode protective layer.

In an embodiment, the display device further includes a first common layer disposed between the first electrode and the light-emitting layer; and a second common layer disposed between the light-emitting layer and the second electrode. The second common layer includes an electron transporting layer disposed on the light-emitting layer; and an electron injection layer disposed between the electron transporting layer and the second electrode. The electron injection layer includes ytterbium (Yb).

In an embodiment of the disclosure, there is provided an electronic device includes a display device displaying an image; a memory storing an application; a processor executing the application and transmitting an image data signal and an input control signal to the display device; and a power supply module supplying power to the display device. The display device includes a substrate including a display area in which light-emitting areas are arranged; a circuit layer disposed on the substrate; and an element layer disposed on the circuit layer. The element layer includes light-emitting devices disposed in the light-emitting areas. Each of the light-emitting devices includes a first electrode disposed on the circuit layer; a light-emitting layer disposed on the first electrode; and a second electrode disposed on the light-emitting layer. The second electrode includes a main layer disposed on the light-emitting layer and including a pure metal material; and an anchor layer disposed on the main layer.

In an embodiment, the main layer has a thickness of about 5 nm to about 30 nm. The pure metal material includes pure silver. The anchor layer has a thickness smaller than the thickness of the main layer, and includes a metal material having a larger atomic weight than an atomic weight of the pure metal material or a larger atomic radius than an atomic radius of the pure metal material.

In an embodiment, the thickness of the anchor layer is about 0.5 nm to about 3 nm.

In an embodiment, the display device further includes an electrode protective layer covering the second electrode of the element layer. The first electrode reflects light from the light-emitting layer. The light from the light-emitting layer is emitted through the second electrode. The anchor layer is disposed between the main layer and the electrode protective layer.

In an embodiment, the light-emitting device in embodiments includes the first electrode and the second electrode, and the light-emitting layer disposed therebetween. The second electrode includes a main layer including a pure metal material, and an anchor layer disposed on the main layer.

In an embodiment, as the main layer of the second electrode disposed on the light-emitting layer includes the pure metal material, the second electrode may be disposed with a relatively thin thickness of about 5 nm to about 30 nm using a vacuum thermal deposition process. Accordingly, damage to the light-emitting layer caused by the process of disposing the second electrode may be reduced, which may be advantageous in improving the photoelectric conversion efficiency of the light-emitting device.

In an embodiment, the second electrode may include the anchor layer disposed on the main layer, and the anchor layer may include a metal element having a larger atomic weight or larger atomic radius than the pure metal material of the main layer.

As a result, even when the main layer includes or consists of a pure metal material that does not include impurities, defects in which atoms of the pure metal material diffuse to the surroundings or are condensed by heat may be reduced by the anchor layer.

That is, even when the impurities are removed, the thin film of the second electrode may be maintained, so that the uniformity, reliability, and lifespan of the light-emitting device may be improved.

In addition, since the increase in resistance and decrease in light transmittance of the second electrode due to the impurities may be prevented, the photoelectric conversion efficiency and light emission efficiency of the light-emitting device may be improved.

By including such a light-emitting device in the display device, the display device may be advantageously improved in terms of luminance and power consumption.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other advantages and features of the disclosure will become more apparent by describing in detail embodiments thereof with reference to the attached drawings, in which:

FIG. 1 is a perspective view illustrating an embodiment of a display device;

FIG. 2 is a plan view illustrating the display device of FIG. 1;

FIG. 3 is a cross-sectional view taken along line A-A′ of FIG. 2;

FIG. 4 is a plan view illustrating a substrate and a circuit layer of FIG. 3;

FIG. 5 is an equivalent circuit diagram illustrating a light-emitting pixel driver of FIG. 4;

FIG. 6 is a plan view illustrating portion B of FIG. 2;

FIG. 7 is a cross-sectional view illustrating an embodiment of a light-emitting pixel driver and a light-emitting device;

FIG. 8 is an enlarged view illustrating portion C of FIG. 7;

FIG. 9 is a simulation graph illustrating a distribution of silver atoms before heat treatment, in a second common layer, a second electrode, and an electrode protective layer in an embodiment and a comparative example; and

FIG. 10 is a simulation graph illustrating a distribution of silver atoms after heat treatment, in a second common layer, a second electrode, and an electrode protective layer in an embodiment and a comparative example.

FIG. 11 is a block diagram of an embodiment of an electronic device according to the disclosure.

FIG. 12 is a schematic diagram of various embodiments of an electronic device according to the disclosure.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure. In the accompanying drawing figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it may be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device disposed “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

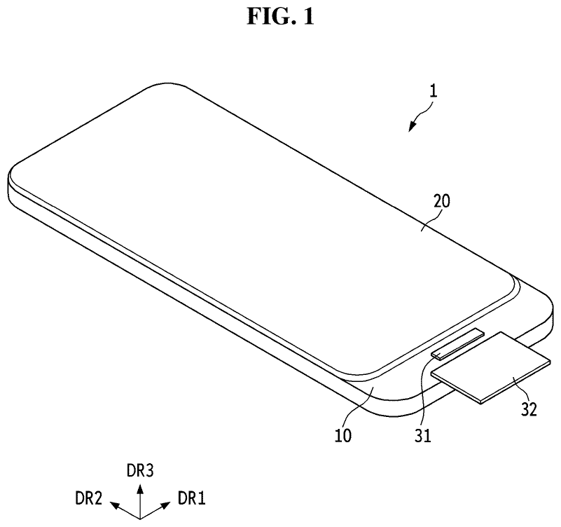

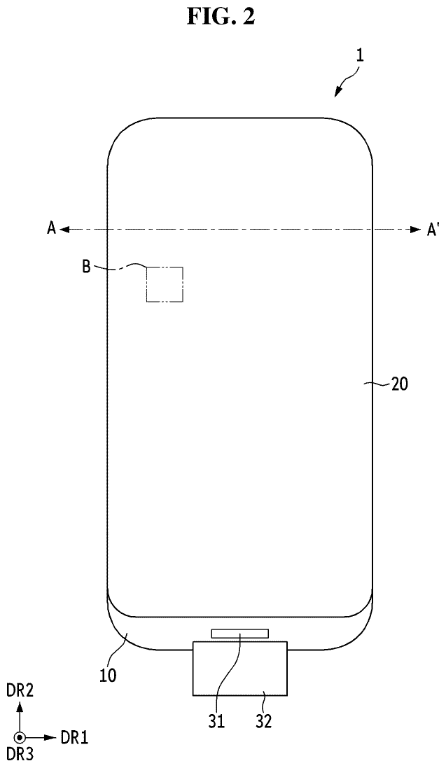

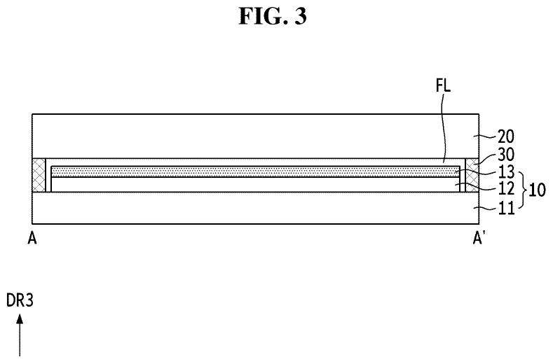

FIG. 1 is a perspective view illustrating an embodiment of a display device. FIG. 2 is a plan view illustrating the display device of FIG. 1. FIG. 3 is a cross-sectional view taken along line A-A′ of FIG. 2.

Referring to FIGS. 1 and 2, a display device 1 is a device that displays a moving image or a still image, and may be used as a display screen of each of various products such as a television, a laptop computer, a monitor, a billboard, and an Internet of Things (“IoT”) device as well as portable electronic devices such as a mobile phone, a smartphone, a tablet personal computer, a smartwatch, a watch phone, a mobile communication terminal, an electronic organizer, an electronic book, a portable multimedia player (“PMP”), a navigation device, and an ultra mobile personal computer (“UMPC”).

The display device 1 may be a light-emitting display device such as an organic light-emitting display device using an organic light-emitting diode, a quantum dot light-emitting display device including a quantum dot light-emitting layer, an inorganic light-emitting display device including an inorganic semiconductor, and a micro light-emitting display device using a micro or nano light-emitting diode (micro or nano LED). Hereinafter, the description will be mainly made based on the fact that the display device 1 is an organic light-emitting display device. However, the disclosure is not limited thereto and may be applied to display devices including organic insulating materials, organic light-emitting materials, and metal materials.

The display device 1 may be in the form of a flat plate in a first direction DR1 and a second direction DR2, but is not limited thereto. In an embodiment, the display device 1 may include curved surface portions formed at left and right distal ends thereof and having a constant curvature or a variable curvature, for example. In addition, the display device 1 may be flexibly formed to be curved, bent, folded, or rolled.

A display surface of the display device 1 may have a quadrangular shape, e.g., rectangular shape having short sides in the first direction DR1 and long sides in the second direction DR2. However, this is merely one of embodiments, and the display surface of the display device 1 may be implemented in various shapes.

In an embodiment, the display surface may be formed in a rounded shape so that a corner where the short side in the first direction DR1 and the long side in the second direction DR2 meet has a predetermined curvature. In an alternative embodiment, the display surface may be in the shape of a polygon, circle, or ellipse.

The display device 1 may include a first substrate 10 that emits light, and a second substrate 20 that faces the first substrate 10 in a third direction DR3 and transmits light.

Each of the first substrate 10 and the second substrate 20 may be in the form of a flat plate in the plane of the first direction DR1 and the second direction DR2.

FIG. 1 illustrates that the first substrate 10 is in the form of a flat plate, but the disclosure is not limited thereto. In an embodiment, the first substrate 10 may be in the form in which at least one of the long sides in the second direction DR2 is bent, for example. In addition, the first substrate 10 may be flexibly formed to be curved, bent, folded, or rolled.

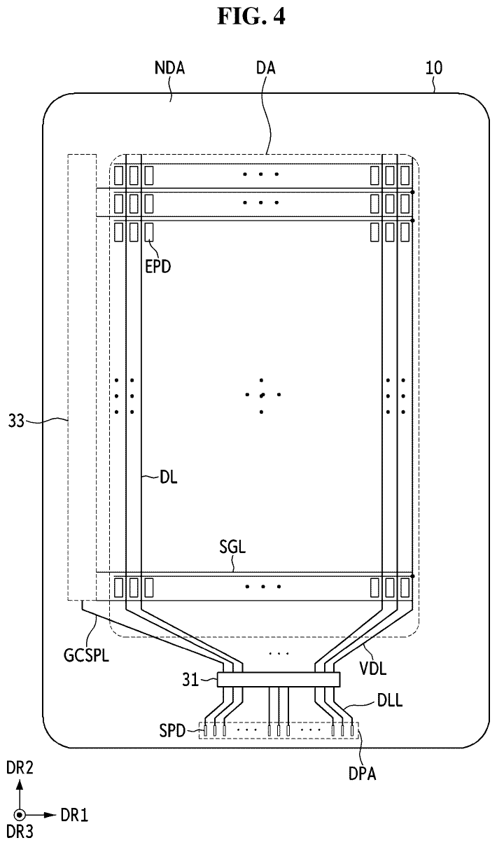

The display device 1 may further include a display driving circuit 31 that supplies data signals to data lines (DL in FIG. 4) of a circuit layer (12 in FIG. 3) of the first substrate 10, and a circuit board 32 for supplying various signals and power to the circuit layer (12 in FIG. 3) of the first substrate 10 and the display driving circuit 31.

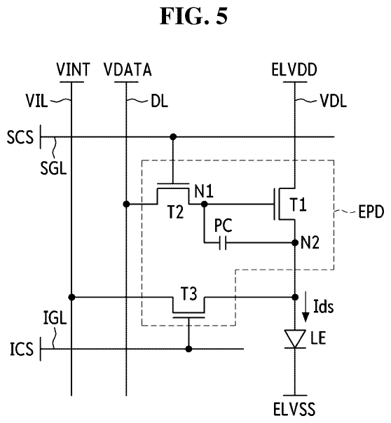

The display driving circuit 31 or the circuit board 32 may supply a first power (ELVDD in FIG. 5) to a first power line (VDL in FIG. 4) of the first substrate 10.

The display driving circuit 31 may supply a scan control signal to a scan driver (33 in FIG. 4) built into the first substrate 10.

The display driving circuit 31 may be provided as an integrated circuit (“IC”).

The integrated circuit chip of the display driving circuit 31 may be directly disposed (e.g., mounted) on the first substrate 110 in a chip on glass (“COG”) manner, a chip on plastic (“COP”) manner, or an ultrasonic bonding manner. In this case, as illustrated in FIG. 2, the integrated circuit chip of the display driving circuit 31 may be disposed in an area of the first substrate 10 that does not overlap the second substrate 20.

In an alternative embodiment, the integrated circuit chip of the display driving circuit 31 may also be disposed (e.g., mounted) on the circuit board 32.

The circuit board 32 may include an anisotropic conductive film. The circuit board 32 may be a flexible film such as a flexible printed circuit board, a printed circuit board, or a chip on film.

The circuit board 32 may be attached to and electrically connected to signal pads (SPD in FIG. 4) disposed in a non-display area NDA of the first substrate 10.

Referring to FIG. 3, the first substrate 10 may include a substrate 11, a circuit layer 12 disposed on the substrate 11, and an element layer 13 disposed on the circuit layer 12.

The substrate 11 may include a display area DA from which light is emitted and a non-display area NDA disposed around the display area DA.

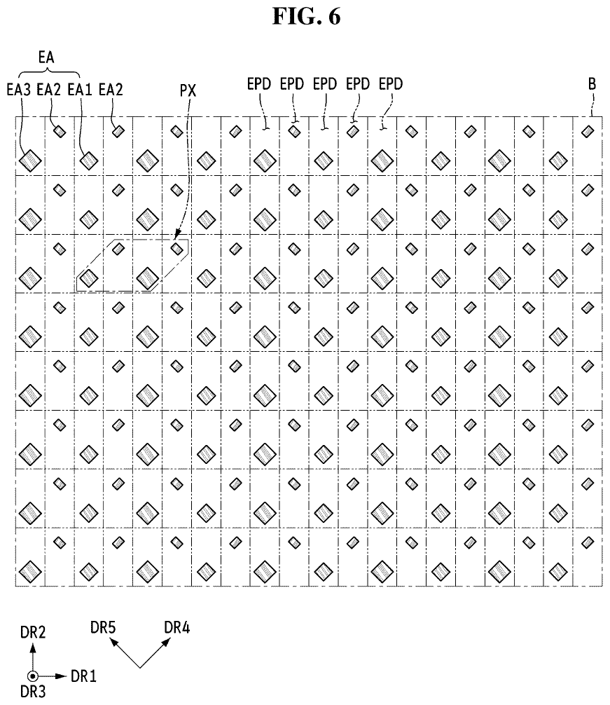

Light-emitting areas (EA in FIG. 6) may be arranged in the display area DA.

The element layer 13 may include light-emitting devices (LE in FIG. 5) disposed in the light-emitting areas EA.

The circuit layer 12 may include light-emitting pixel drivers (EPD in FIG. 4) that are electrically connected to the light-emitting devices.

The display driving circuit 31 may generate a data signal (VDATA in FIG. 5) according to an image signal.

The light-emitting pixel drivers EPD may transmit a driving current having the magnitude corresponding to the data signal (VDATA in FIG. 5) supplied from the display driving circuit 31 to the light-emitting devices LE.

The light-emitting devices LE may emit light with luminance corresponding to a driving current (Ids in FIG. 5) supplied from the light-emitting pixel drivers EPD.

As a result, the display device 1 may provide a function of displaying an image.

In an alternative embodiment, the display device 1 may further include a touch sensor that senses the coordinates of a point touched by a user on the display surface from which light for displaying the image is emitted.

The touch sensor may be attached to one surface of the second substrate 20 or may be disposed between the first substrate 10 and the second substrate 20.

The second substrate 20 may be a means for providing rigidity to protect against external physical and electrical shocks. The second substrate 20 may include or consist of a transparent material having insulating properties and rigidity.

By embodiments, the display device 1 may include a sealing layer 30 that bonds the first substrate 10 and the second substrate 20.

The sealing layer 30 may be disposed in the non-display area NDA between the first substrate 10 and the second substrate 20.

The display device 1 may include a filling layer FL that fills a space between the first substrate 10 and the second substrate 20.

FIG. 4 is a plan view illustrating a substrate and a circuit layer of FIG. 3.

Referring to FIG. 4, the substrate 11 of the display device 1 may include a display area DA from which light for displaying an image is emitted, and a non-display area NDA surrounding the display area DA.

The circuit layer 12 may include light-emitting pixel drivers EPD arranged in the first direction DR1 and the second direction DR2 in the display area DA, and lines supplying signals or power to the light-emitting pixel drivers EPD.

The lines of the circuit layer 12 may include a scan gate line SGL that transmits a scan signal (SCS in FIG. 5), a data line DL that transmits a data signal (VDATA in FIG. 5), and a first power line VDL that transmits a first power (ELVDD in FIG. 5).

The scan gate line SGL may extend in the first direction DR1.

The data line DL may extend in the second direction DR2.

The first power line VDL may extend in either the first direction DR1 or the second direction DR2. In an embodiment, the first power line VDL may extend in the second direction DR2 like the data line DL.

The non-display area NDA may include a display pad area DPA disposed next (adjacent) to an edge of the substrate 11.

The circuit layer 12 may further include signal pads SPD disposed in the display pad area DPA of the non-display area NDA and electrically connected to the circuit board (32 in FIGS. 1 and 2), and data link lines DLL electrically connecting some of the signal pads SPD and the display driving circuit 31.

The circuit layer 12 may include a gate driver 33 disposed in a portion of the non-display area NDA.

The gate driver 33 may be electrically connected to the display driving circuit 31 or at least one signal pad SPD through at least one gate control supply line GCSPL.

The gate driver 33 may output a scan signal SCS to the scan gate lines SGL based on a gate control signal and gate level power supplied through at least one gate control supply line GCSPL.

The gate driver 33 may face one side of the display area DA in the first direction DR1. However, this is merely one of embodiments, and the gate driver 33 may be disposed in another portion of the non-display area NDA next (adjacent) to a right side of the display area DA. In an alternative embodiment, the gate driver 33 may also be disposed on opposite sides of the display area DA in the left and right directions.

FIG. 5 is an equivalent circuit diagram illustrating a light-emitting pixel driver of FIG. 4.

Referring to FIG. 5, the light-emitting pixel driver EPD may be electrically connected between the first power ELVDD and the light-emitting device LE, and the light-emitting device LE may be electrically connected between the light-emitting pixel driver EPD and the second power ELVSS.

The light-emitting device LE may be an organic light-emitting diode (“LED”) including an organic light-emitting layer, a quantum dot LED including a quantum dot light-emitting layer, a micro LED, or an inorganic LED including an inorganic semiconductor.

The second power ELVSS may have a lower voltage level than that of the first power ELVDD.

That is, an anode electrode of the light-emitting device LE may be electrically connected to the light-emitting pixel driver EPD, and a cathode electrode of the light-emitting device LE may be electrically connected to the second power ELVSS.

The circuit layer 120 may include a scan gate line SGL that transmits a scan signal SCS to the light-emitting pixel drivers EPD, an initialization gate line IGL that transmits an initialization control signal ICS to the light-emitting pixel drivers EPD, a data line DL that transmits a data signal VDATA to the light-emitting pixel drivers EPD, an initialization voltage line VIL that transmits an initialization voltage VINT to the light-emitting pixel drivers EPD, and a first power line VDL that transmits a first power ELVDD to the light-emitting pixel drivers EPD.

The light-emitting pixel driver EPD may include a first transistor T1 that generates a driving current for the light-emitting device LE, and one or more transistors T2 and T3 and one or more capacitors PC electrically connected to the first transistor T1

The first transistor T1 may be electrically connected between the first power line VDL and the light-emitting device LE.

A gate electrode of the first transistor T1 may be electrically connected to the second transistor T2 through a first node N1.

A first electrode of the first transistor T1 may be electrically connected to the first power line VDL.

A second electrode of the first transistor T1 may be electrically connected to an anode electrode of the light-emitting device LE through a second node N2.

The second transistor T2 may be electrically connected between the data line DL and the first node N1.

A gate electrode of the second transistor T2 may be electrically connected to the scan gate line SGL. That is, the second transistor T2 may be turned on by the scan signal SCS of the scan gate line SGL.

When the second transistor T2 is turned on, the data signal VDATA of the data line DL may be transmitted to the gate electrode of the first transistor T1 through the first node N1.

Accordingly, a voltage difference between the gate electrode of the first transistor T1 and the first electrode of the first transistor T1, that is, a voltage difference between the gate and the source may correspond to a voltage difference between the first power ELVDD and the data signal Vdata and may be greater than a threshold voltage of the first transistor T1. Accordingly, as the first transistor T1 is turned on, a source-drain current Ids having a size corresponding to the data signal VDATA may be generated between the first electrode and the second electrode of the first transistor T1. In addition, the source-drain current Ids of the first transistor T1 may be supplied as a driving current to the light-emitting device LE through the second node N2.

Therefore, since the driving current Ids having the size corresponding to the data signal VDATA is supplied to the light-emitting device LE, the light-emitting device LE may emit light with luminance corresponding to the data signal VDATA.

The capacitor PC may be electrically connected between the first node N1 and the second node N2.

The capacitor PC may be charged based on the data signal VDATA transmitted to the first node N1.

Since the capacitor PC is electrically connected to the gate electrode of the first transistor T1 through the first node N1, the turn-on state of the first transistor T1 may be maintained for a period corresponding to a voltage charged to the capacitor PC.

The third transistor T3 may be electrically connected between the initialization voltage line VIL and the second node N2.

A gate electrode of the third transistor T3 may be electrically connected to the initialization gate line IGL. That is, the third transistor T3 may be turned on by the initialization control signal ICS of the initialization gate line IGL.

When the third transistor T3 is turned on, a potential of the second node N2, that is, a potential of the anode electrode of the light-emitting device LE may be initialized to the initialization voltage VINT of the initialization voltage line VIL.

FIG. 5 illustrates that the light-emitting pixel driver EPD has a three-transistor-one-capacitor (“3T1C”) structure including a first thin film transistor T1, a second thin film transistor T2, a third thin film transistor T3, and one pixel capacitor PC, but this is merely one of embodiments. That is, the light-emitting pixel driver EPD in the embodiments is not limited to the 3T1C structure illustrated in FIG. 5, and may be changed differently from the structure illustrated in FIG. 5 as desired. In an embodiment, the light-emitting pixel driver EPD may not include the third thin film transistor T3. In another embodiment, the light-emitting pixel driver EPD may further include a thin film transistor for initializing a potential of the first node N1.

In addition, as illustrated in FIG. 5, each of the first, second, and third transistors T1, T2, and T3 may be an N-type metal oxide semiconductor field effect transistor (“MOSFET”). However, this is merely one of embodiments, and at least one of the first, second and third transistors T1, T2, and T3 may also be a P-type MOSFET.

FIG. 6 is a plan view illustrating portion B of FIG. 2.

Referring to FIG. 6, the display area DA of the substrate 11 of the display device 1 in embodiments may include light-emitting areas EA arranged parallel to each other, and a non-light-emitting area NEA, which is a spaced area between the light-emitting areas EA.

The element layer (13 in FIG. 3) may include light-emitting devices (LE in FIG. 5) each disposed in the light-emitting areas EA.

The light-emitting areas EA may have a rhombic planar shape or a rectangular planar shape. However, this is merely one of embodiments, and the planar shape of the light-emitting areas EA in an embodiment is not limited to that illustrated in FIG. 6. That is, the light-emitting areas EA may have a polygonal planar shape such as a square, pentagon, or hexagon, or a circular or oval planar shape including curved edges.

In embodiments, the light-emitting areas EA may include a first light-emitting area EA1 that emits light in a first wavelength band, a second light-emitting area EA2 that emits light in a second wavelength band lower than the first wavelength band, and a third light-emitting area EA3 that emits light in a third wavelength band lower than the second wavelength band.

In an embodiment, the first wavelength band is about 600 nanometers (nm) to about 750 nm, and the light in the first wavelength band may be red. The second wavelength band is about 480 nm to about 560 nm, and the light in the second wavelength band may be green. The third wavelength band is about 370 nm to about 460 nm, and the light in the third wavelength band may be blue.

The first light-emitting areas EA1 and the third light-emitting areas EA3 may be alternately disposed in the first direction DR1 or the second direction DR2.

The second light-emitting areas EA2 may be arranged to be parallel to each other in the first direction DR1 or the second direction DR2.

The second light-emitting areas EA2 may be next (adjacent) to the first light-emitting areas EA1 and the third light-emitting areas EA3 in fourth and fifth directions DR4 and DR5 which are diagonal directions intersecting the first and second directions DR1 and DR2.

Pixels PX that display each luminance and color may be provided by the first light-emitting area EA1, the second light-emitting area EA2, and the third light-emitting area EA3 next (adjacent) to each other among the light-emitting areas EA.

The pixels PX may be basic units that display various colors, including white, at predetermined luminance.

Each of the pixels PX may include at least one first light-emitting area EA1, at least one second light-emitting area EA2, and at least one third light-emitting area EA3 next (adjacent) to each other. Accordingly, each of the pixels PX may display various colors through mixing of light emitted from the first, second, and third light-emitting areas EA1, EA2, and EA3 next (adjacent) to each other.

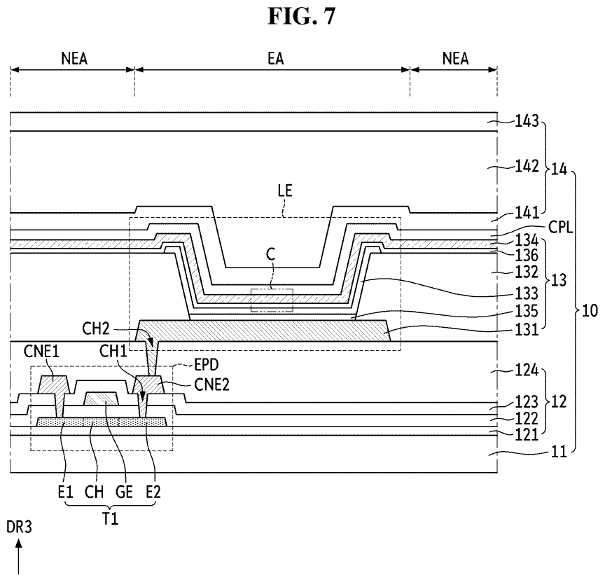

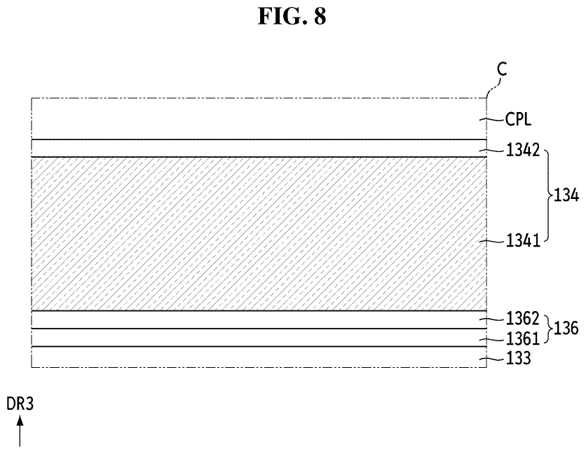

FIG. 7 is a cross-sectional view illustrating an embodiment of a light-emitting pixel driver and a light-emitting device. FIG. 8 is an enlarged view illustrating portion C of FIG. 7.

Referring to FIG. 7, the first substrate 10 of the display device 1 in an embodiment includes a substrate 11, a circuit layer 12 disposed on the substrate 11, and an element layer 13 disposed on the circuit layer 12.

The first substrate 10 of the display device 1 may further include a sealing layer 14 disposed on the element layer 13.

The substrate 11 may include a display area DA including light-emitting areas EA arranged in parallel with each other and a non-light-emitting area NEA disposed therebetween.

The circuit layer 12 may include a buffer layer 121 disposed on the substrate 11, a semiconductor layer (including a channel portion CH, a first electrode portion E1, and a second electrode portion E2) disposed on the buffer layer 121, a gate insulating layer 122 covering the semiconductor layer, a gate conductive layer (including a gate electrode GE) disposed on the gate insulating layer 122, an inter-insulating layer 123 covering the gate conductive layer, a source-drain conductive layer (including a first connection electrode CNE1 and a second connection electrode CNE2) disposed on the inter-insulating layer 123, and a planarization layer 124 covering the source-drain conductive layer.

Each of the buffer layer 121 and the gate insulating layer 122 may include an inorganic insulating material.

Each of the inter-insulating layer 123 and the planarization layer 124 may include an inorganic insulating material or an organic insulating material.

The circuit layer 12 may include light-emitting pixel drivers EPD each corresponding to the light-emitting areas EA.

Each of the light-emitting pixel drivers EPD may include a first transistor T1 that generates a driving current (Ids in FIG. 5) of the light-emitting device LE.

The first transistor T1 may include a channel portion CH, a first electrode portion E1, and a second electrode portion E2 disposed in the semiconductor layer on the buffer layer 121, and a gate electrode GE disposed in the gate conductive layer on the gate insulating layer 122.

The first electrode portion E1 may be connected to one side of the channel portion CH.

The second electrode portion E2 may be connected to an opposite side of the channel portion CH.

The gate electrode GE may overlap the channel portion CH.

The first connection electrode CNE1 may be electrically connected to the first electrode portion E1 of the first transistor T1. In an embodiment, the first electrode portion E1 of the first transistor T1 may be electrically connected to the first power line (VDL in FIG. 5) through the first connection electrode CNE1.

The second connection electrode CNE2 may be electrically connected to the second electrode portion E2 of the first transistor T1 through a first connection hole CH1.

The element layer 13 may include light-emitting devices LE disposed in light-emitting areas EA.

Each of the light-emitting devices LE may include a first electrode 131 and a second electrode 134 opposing each other, and a light-emitting layer 133 disposed between the first electrode 131 and the second electrode 134.

In an embodiment, each of the light-emitting devices LE may further include first common layers 135 disposed between the first electrodes 131 and the light-emitting layers 133, and a second common layer 136 disposed between the light-emitting layers 133 and the second electrode 134.

That is, the element layer 13 may include first electrodes 131 each disposed in the light-emitting areas EA, a pixel defining layer 132 disposed in the non-light-emitting area NEA between the light-emitting areas EA and covering an edge of the first electrodes 131, first common layers 135 each disposed on the first electrodes 131, light-emitting layers 133 each disposed on the first common layers 135, a second common layer 136 disposed on the pixel defining layer 132 and the light-emitting layers 133, and a second electrode 134 disposed on the second common layer 136.

The first electrode 131 may be electrically connected to the light-emitting pixel driver EPD of the circuit layer 12, and the light-emitting pixel driver EPD may be electrically connected to the first power line (VDL in FIG. 5) that transmits the first power (ELVDD in FIG. 5).

The second power (ELVSS of FIG. 5) having a lower voltage level than that of the first power ELVDD may be applied to the second electrode 134.

In this case, the first common layer 135 may include a hole transporting layer disposed under the light-emitting layer 133 and including a hole transport material. In an alternative embodiment, the first common layer 135 may further include a hole injection layer disposed between the hole transporting layer and the first electrode 131 and including a hole injection material.

The second common layer 136 may include an electron transporting layer (1361 in FIG. 8) disposed on the light-emitting layer 133 and including an electron transporting material. In an alternative embodiment, the second common layer 136 may further include an electron injection layer (1362 in FIG. 8) disposed between the electron transporting layer 1361 and the second electrode 134 and including an electron injection material.

The first electrode 131 may be disposed on the planarization layer 124 of the circuit layer 12 and may overlap the light-emitting area EA.

The first electrode 131 may be electrically connected to the second connection electrode CNE2 through a second connection hole CH2. As a result, the first electrode 131 may be electrically connected to the first transistor T1 of the light-emitting pixel driver EPD. Such a first electrode 131 may be a pixel electrode or an anode electrode.

The first electrode 131 may include a reflective layer including a reflective metal material and a blocking layer for preventing diffusion of the metal material of the reflective layer. The reflective layer may include silver (Ag) or an alloy including or consisting of silver (Ag). The blocking layer may include a transparent conductive oxide, such as indium tin oxide (“ITO”).

In an embodiment, the first electrode 131 may include a triple layer structure of ITO/Ag/ITO.

The pixel defining layer 132 may be disposed on the planarization layer 124 of the circuit layer 12, overlap the non-light-emitting area NEA, and cover an edge of the first electrode 131.

The pixel defining layer 132 may include an organic insulating material.

The light-emitting layer 133 may include an organic light-emitting material and may be disposed in the light-emitting area EA.

The second electrode 134 may be entirely disposed in the display area (DA in FIG. 4) including the light-emitting areas EA and the non-light-emitting area NEA. Such a second electrode 134 may be a common electrode or a cathode electrode.

As illustrated in FIG. 8, in an embodiment, the second electrode 134 may include a main layer 1341 disposed on the light-emitting layer 133 and including a pure metal material, and an anchor layer 1342 disposed on the main layer 1341. In the description, the term “pure metal material” may refer toa metal material composed entirely of one type of metal atom, for example.

The main layer 1341 may be disposed as a thin film having a thickness of about 5 nm to about 30 nm.

The pure metal material forming the main layer 1341 may include pure silver.

The main layer 1341 may be disposed to a thickness of about 5 micrometers (μm) to about 30 μm. In an embodiment, the main layer 1341 may be disposed to a thickness of about 10 μm.

When the thickness of the main layer 1341 is less than 5 μm, it may be difficult for the main layer 1341 to maintain the form of a thin film.

In addition, when the thickness of the main layer 1341 exceeds 30 μm, it may be difficult to improve a light transmittance.

The anchor layer 1342 may be disposed on the main layer 1341 with a thickness smaller than that of the main layer 1341. The anchor layer 1342 is intended to prevent condensation and diffusion of the pure metal material of the main layer 1341.

To this end, the anchor layer 1342 may include a metal material having a larger atomic weight than that of the pure metal material of the main layer 1341 or a larger atomic radius than that of the pure metal material.

In an embodiment, when the pure metal material of the main layer 1341 is pure silver, the anchor layer 1342 may be an oxide including indium (In), tin (Sn), zinc (Zn), or tungsten (W).

That is, the anchor layer 1342 may include at least one of tungsten oxide, indium tin oxide (“ITO”), and indium zinc oxide (“IZO”).

In an alternative embodiment, when the pure metal material of the main layer 1341 is pure silver, the anchor layer 1342 may include at least one of ytterbium (Yb), bismuth (Bi), cesium (Cs), samarium (Sm), and barium (Ba). In an embodiment, the anchor layer 1342 may include ytterbium (Yb).

The anchor layer 1342 may be disposed to a thickness of about 0.5 μm to about 3 μm. In an embodiment, the thickness of the anchor layer 1342 may be about 1 μm.

When the thickness of the anchor layer 1342 is less than 0.5 μm, it may be difficult for the anchor layer 1342 to be disposed in the form of a thin film or to maintain the form of a thin film.

When the thickness of the anchor layer 1342 exceeds 3 μm, the light transmittance of the second electrode 134 may be significantly reduced beyond a critical level by the anchor layer 1342.

In addition, the electron injection layer 1362 of the second common layer 136 disposed between the electron transporting layer 1361 and the second electrode 134 may include ytterbium (Yb).

In this way, as the pure metal material of the main layer 1341 is disposed in a sandwich form between the ytterbium Yb of the anchor layer 1342 and the ytterbium Yb of the electron injection layer 1362, the condensation and diffusion of the pure metal material of the main layer 1341 may be further blocked, thereby making it possible to more easily maintain the form of a thin film form of the main layer 1341.

In addition, since the main layer 1341 is stacked on the electron injection layer 1362 of ytterbium (Yb), it may be more advantageous for the main layer 1341 to be disposed in the form of a thin film with a relatively uniform thickness.

As illustrated in FIG. 7, in an embodiment, the first substrate 10 of the display device 1 may further include an electrode protective layer CPL covering the second electrode 134 of the element layer 13.

The electrode protective layer CPL is intended to protect the second electrode 134 of the thin film from physical and electrical shocks.

The electrode protective layer CPL may include an inorganic insulating material or an organic insulating material.

The electrode protective layer CPL may be disposed on the anchor layer 1342.

In other words, the anchor layer 1342 may be disposed between the main layer 1341 and the electrode protective layer CPL.

Accordingly, the amount and range of diffusion of the pure metal material of the main layer 1341 into the electrode protective layer CPL may be reduced by the anchor layer 1342.

The sealing layer 14 is intended to block permeation of oxygen or moisture into the element layer 13 and to relieve electrical or physical shock to the circuit layer 12 and the element layer 13.

The sealing layer 14 may include a first sealing layer 141 disposed on the element layer 13 and including an inorganic insulating material, a second sealing layer 142 disposed on the first sealing layer 141, overlapping the display area DA, and including an organic insulating material, and a third sealing layer 143 covering the second sealing layer 142 and including an inorganic insulating material.

As described above, in an embodiment, the second electrode 134 includes the main layer 1341 disposed on the light-emitting layer 133, and the anchor layer 1342 covering the main layer 1341.

As the main layer 1341 includes or consists of the pure metal material such as pure silver, it may be disposed into a thin film using a vacuum thermal deposition method.

Accordingly, damage to the light-emitting layer 133 and damage to the second common layer 136 caused by a process of disposing the main layer 1341 may be prevented.

In addition, when the anchor layer 1342 includes at least one of ytterbium (Yb), bismuth (Bi), cesium (Cs), samarium (Sm), and barium (Ba), the anchor layer 1342 may be disposed by a vacuum thermal deposition method, and thus, damage to the light-emitting layer 133 and damage to the second common layer 136 caused by a process of disposing the anchor layer 1342 may be prevented.

Therefore, the reliability, uniformity and lifespan of the light-emitting device LE may be improved.

In an embodiment, as the second electrode 134 includes the main layer 1341 including or consisting of the pure metal material and the anchor layer 1342 for preventing diffusion and condensation of the pure metal material, the second electrode 134 does not desire impurities for thin film stability.

That is, since the second electrode 134 of the light-emitting device LE in an embodiment does not include impurities such as magnesium (Mg) for thin film stability, a decrease in the light transmittance and an increase in the resistance of the second electrode 134 due to the impurities may be prevented. Therefore, the light emission efficiency and photoelectric conversion efficiency of the light-emitting device LE may be improved.

That is, as a result of examining simulation results for the resistance and light transmittance of the second electrode 134, it was confirmed that the resistance of the second electrode was 10.2 ohm per square (Ω/□e), and the light transmittance of the second electrode was 63.7%, in the case of a comparative example in which the second electrode 134 includes a silver-magnesium alloy (AgMg) doped with 5% of magnesium (Mg) impurity material and is disposed with a thickness of 10.5 μm.

In the case of an embodiment in which the second electrode 134 includes a main layer 1341 disposed with a pure silver material having a thickness of 10 μm, and an anchor layer 1342 disposed with ytterbium (Yb) having a thickness of 1 μm, it was confirmed that the resistance of the second electrode 134 was 6.5Ω/□, which was reduced by 36.3% compared to the comparative example, and the light transmittance of the second electrode 134 was 70.6%, which was increased by 10.8% compared to the comparative example.

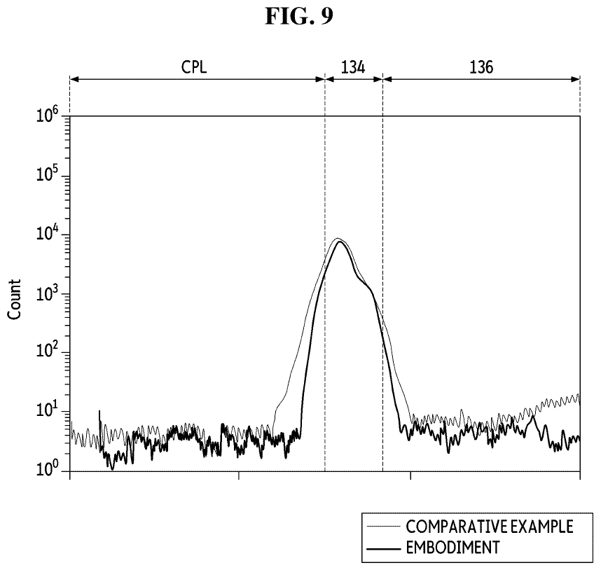

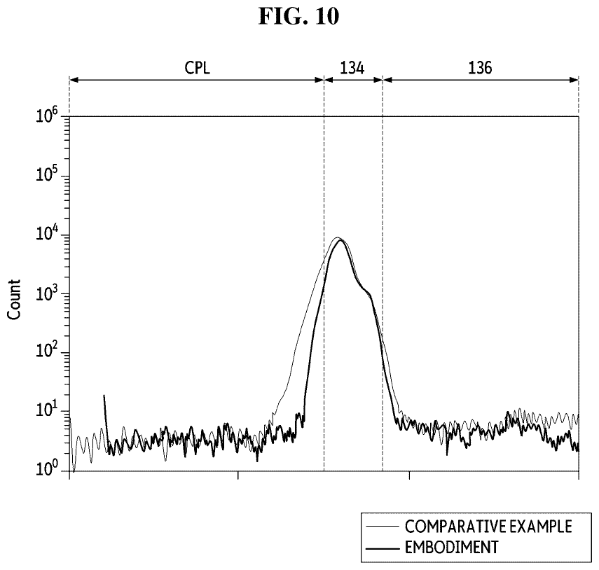

FIG. 9 is a simulation graph illustrating a distribution of silver atoms before heat treatment, in a second common layer, a second electrode, and an electrode protective layer in an embodiment and a comparative example. FIG. 10 is a simulation graph illustrating a distribution of silver atoms after heat treatment, in a second common layer, a second electrode, and an electrode protective layer in an embodiment and a comparative example.

In FIGS. 9 and 10, the second electrode 134 according to the comparative example includes a silver-magnesium alloy (AgMg) doped with 5% of an impurity material of magnesium (Mg), and is disposed to a thickness of 10.5 μm.

As illustrated in FIG. 9, it is confirmed that the range in which silver atoms diffuse into the second common layer 136 and the electrode protective layer CPL around the second electrode 134 before heat treatment is narrower in an embodiment than in the comparative example.

In addition, as illustrated in FIG. 10, it is confirmed that the diffusion range of silver atoms due to heat treatment is narrower in an embodiment than in the comparative example. That is, it may be seen that the second electrode 134 in an embodiment has lower reactivity to heat than that of the comparative example because the silver atoms of the main layer 1341 are fixed by the anchor layer 1342.

Therefore, the characteristic uniformity, reliability, and lifespan of the light-emitting device LE in an embodiment may be improved.

The display device in an embodiment of the disclosure may be applied to various electronic devices. The electronic device according to the embodiment of the disclosure includes the display device described above, and may further include modules or devices having additional functions in addition to the display device.

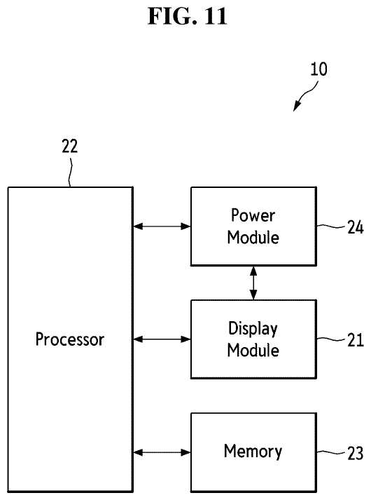

FIG. 11 is a block diagram of an embodiment of an electronic device according to the disclosure.

Referring to FIG. 11, the electronic device 1 in an embodiment of the disclosure may include a display module 21, a processor 22, a memory 23, and a power module 24.

The processor 22 may include at least one of a central processing unit (“CPU”), an application processor (“AP”), a graphic processing unit (“GPU”), a communication processor (“CP”), an image signal processor (“ISP”), and a controller.

The memory 15 may store data information desired for the operation of the processor 22 or the display module 21. When the processor 22 executes an application stored in the memory 23, an image data signal and/or an input control signal is transmitted to the display module 21, and the display module 21 may process the received signal and output image information through a display screen.

The power module 24 may include a power supply module such as, for example a power adapter or a battery, and a power conversion module that converts the power supplied by the power supply module to generate power desired for the operation of the electronic device 1.

At least one of the components of the electronic device 1 according to the embodiment of the disclosure may be included in the display device 10 in the embodiments of the disclosure. In addition, some modules of the individual modules functionally included in one module may be included in the display device 10, and other modules may be provided separately from the display device 10. In an embodiment, the display device 10 may include the display module 21, and the processor 22, the memory 23, and the power module 24 may be provided in the form of other devices within the electronic device 11 other than the display device 10, for example.

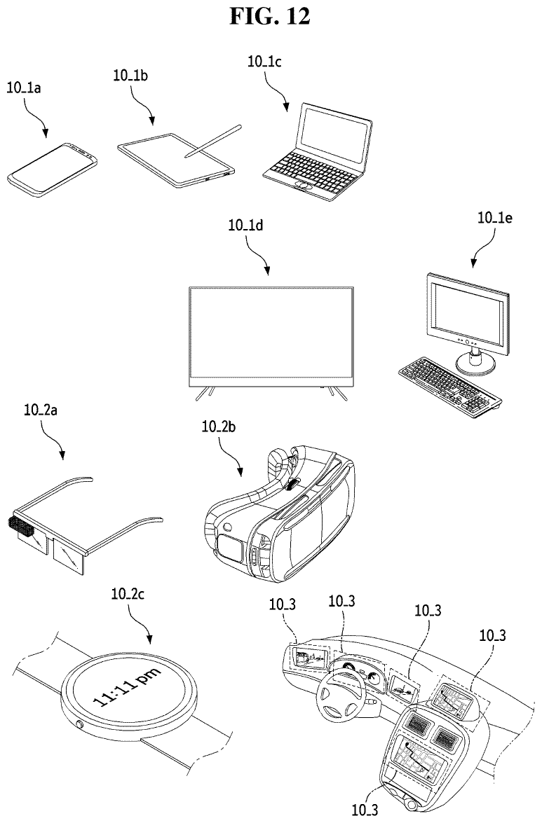

FIG. 12 is a schematic diagram of various embodiments of an electronic device according to the disclosure.

Referring to FIG. 12, various electronic devices to which display devices 10 in embodiments of the disclosure are applied may include not only image display electronic devices such as a smart phone 10_1a, a tablet personal computer 10_1b, a laptop 10_1c, a television (“TV”) 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a center information display (“CID”) and a room mirror display arranged on a dashboard, center fascia, and dashboard of an automobile.

However, the effects of the disclosure are not restricted to the one set forth herein. The above and other effects of the disclosure will become more apparent to one of daily skill in the art to which the disclosure pertains by referencing the claims.

What is claimed is:

1. A light-emitting device comprising:
a first electrode;
a light-emitting layer disposed on the first electrode; and
a second electrode disposed on the light-emitting layer, the second electrode including:
a main layer disposed on the light-emitting layer and including a pure metal material; and
an anchor layer disposed on the main layer.

2. The light-emitting device of claim 1, wherein the main layer has a thickness of about 5 nanometers to about 30 nanometers,
the pure metal material includes pure silver, and
the anchor layer has a thickness smaller than the thickness of the main layer.

3. The light-emitting device of claim 2, wherein the anchor layer includes a metal material having a larger atomic weight than an atomic weight of the pure metal material or a larger atomic radius than an atomic radius of the pure metal material.

4. The light-emitting device of claim 3, wherein the anchor layer includes at least one of tungsten oxide, indium tin oxide, and indium zinc oxide.

5. The light-emitting device of claim 3, wherein the anchor layer includes at least one of ytterbium (Yb), bismuth (Bi), cesium (Cs), samarium (Sm), and barium (Ba).

6. The light-emitting device of claim 5, wherein the thickness of the anchor layer is about 0.5 nanometer to about 3 nanometers.

7. The light-emitting device of claim 2, wherein the first electrode reflects light from the light-emitting layer,
the light-emitting layer is disposed on the first electrode,
the second electrode is disposed on the light-emitting layer,
the light from the light-emitting layer is emitted through the second electrode,
the second electrode is covered with an electrode protective layer, and
the anchor layer is disposed between the main layer and the electrode protective layer.

8. The light-emitting device of claim 7, further comprising:
a first common layer disposed between the first electrode and the light-emitting layer; and
a second common layer disposed between the light-emitting layer and the second electrode,
wherein the second common layer includes:
an electron transporting layer disposed on the light-emitting layer; and
an electron injection layer disposed between the electron transporting layer and the second electrode, and
the electron injection layer includes ytterbium (Yb).

9. A display device comprising:
a substrate including a display area in which light-emitting areas are arranged;
a circuit layer disposed on the substrate; and
an element layer disposed on the circuit layer, the element layer including
light-emitting devices disposed in the light-emitting areas, each of the light-emitting devices including:
a first electrode disposed on the circuit layer;
a light-emitting layer disposed on the first electrode; and
a second electrode disposed on the light-emitting layer, the second electrode including:
a main layer disposed on the light-emitting layer and including a pure metal material; and
an anchor layer disposed on the main layer.

10. The display device of claim 9, wherein the main layer has a thickness of about 5 nanometers to about 30 nanometers,
the pure metal material includes pure silver, and
the anchor layer has a thickness smaller than the thickness of the main layer.

11. The display device of claim 10, wherein the anchor layer includes a metal material having a larger atomic weight than an atomic weight of the pure metal material or a larger atomic radius than an atomic radius of the pure metal material.

12. The display device of claim 11, wherein the anchor layer includes at least one of tungsten oxide, indium tin oxide, and indium zinc oxide.

13. The display device of claim 11, wherein the anchor layer includes at least one of ytterbium (Yb), bismuth (Bi), cesium (Cs), samarium (Sm), and barium (Ba).

14. The display device of claim 13, wherein the thickness of the anchor layer is about 0.5 nanometer to about 3 nanometers.

15. The display device of claim 10, further comprising an electrode protective layer covering the second electrode of the element layer,
wherein the first electrode reflects light from the light-emitting layer,
the light from the light-emitting layer is emitted through the second electrode, and
the anchor layer is disposed between the main layer and the electrode protective layer.

16. The display device of claim 10, further comprising:
a first common layer disposed between the first electrode and the light-emitting layer; and
a second common layer disposed between the light-emitting layer and the second electrode,
wherein the second common layer includes:
an electron transporting layer disposed on the light-emitting layer; and
an electron injection layer disposed between the electron transporting layer and the second electrode, and
the electron injection layer includes ytterbium (Yb).

17. An electronic device comprising:
a display device which displays an image, the display device comprising:
a substrate including a display area in which light-emitting areas are arranged;
a circuit layer disposed on the substrate; and
an element layer disposed on the circuit layer, the element layer including:
light-emitting devices disposed in the light-emitting areas, each of the light-emitting devices including:
a first electrode disposed on the circuit layer;
a light-emitting layer disposed on the first electrode; and
a second electrode disposed on the light-emitting layer, the second electrode including: a main layer disposed on the light-emitting layer and including a pure metal material; and an anchor layer disposed on the main layer;
a memory which stores an application;
a processor which executes the application and transmits an image data signal and an input control signal to the display device; and
a power supply module which supplies power to the display device.

18. The electronic device of claim 17, wherein
the main layer has a thickness of about 5 nanometers to about 30 nanometers,
the pure metal material includes pure silver, and
the anchor layer has a thickness smaller than the thickness of the main layer, and includes a metal material having a larger atomic weight than an atomic weight of the pure metal material or a larger atomic radius than an atomic radius of the pure metal material.

19. The electronic device of claim 18, wherein the thickness of the anchor layer is about 0.5 nanometer to about 3 nanometers.

20. The electronic device of claim 18, wherein the display device further comprises an electrode protective layer covering the second electrode of the element layer,
the first electrode reflects light from the light-emitting layer,
the light from the light-emitting layer is emitted through the second electrode, and
the anchor layer is disposed between the main layer and the electrode protective layer.
